(19) United States
(12) Patent Application Publication
(10) Pub. No.: US 2007/0076386 A1
(43) Pub. Date: Apr. 5, 2007

(54) Optimized light fixture circuit board

(75) Inventor: George Kaelin, Camarillo, CA (US)

Correspondence Address: Michael J. Moffatt, Esq.;FULWIDER PATTON LEE & UTECHT, LLP, Suite 1550, 200 Oceangate, Long Beach, CA, 90732, US

(73) Assignee: Thin-Lite Corporation

(21) Appl. No.: 11/208,799

(22) Filed: Aug. 22, 2005

(51) Int. Cl. H05K 7/00

(52) U.S. Cl. 361/760

(57) ABSTRACT

A square layout of a DC light fixture printed circuit board assembly having no cross-over wiring while maintaining all of the necessary component interconnections comprises a transformer, two transistors, a diode, a resistor, an inductor, and three capacitors all arranged on a square 2¼″×2¼″ printed circuit board. To avoid cross-over wiring, the present inventor has strategically utilized the resistor and two capacitors as “bridges” to complete the necessary connections within the framework of the square configuration. Here, the resistor bridges the connections between the transformer and both the first capacitor as well as the transistor. The second capacitor bridges the connection between the transformer and the inductor, and the third capacitor bridges the connection between the terminal block and the second transistor.

### FIELD OF THE INVENTION

This invention relates generally to electronic lighting circuit boards, and more particularly to an optimized circuit board with a square foot print.

### BACKGROUND OF THE INVENTION

Electronic ballasts used for powering single fluorescent bulbs have traditionally been formed on an elongate rectangular board because of ease of manufacture and because such a configuration permits ample room for the components and interconnections. For certain customer requirements, however, a square footprint would optimize the space allocation while maintaining the original components of the rectangular board. To convert the board to a square configuration would require that the necessary interconnections would be maintained without crossovers, and that all of the previous components would function in the same relationships as before under the new design. However, conflicts in the transformer can upset the operation of the circuit board and prevent successful operation. Therefore, the present inventor is unaware of any DC light fixture circuit board with an inductor, a resistor, three capacitors, two transistors, a transformer, and three terminal blocks having a square circuit board.

### SUMMARY OF THE INVENTION

A square layout of a DC light fixture printed circuit board is presented having no cross-over wiring while maintaining all of the necessary component interconnections. The board comprises a transformer, two transistors, a diode, a resistor, an inductor, and three capacitors all arranged on a square 2¼″×2¼″ breadboard. To avoid cross-over wiring, the present inventor has strategically utilized the resistor and two capacitors as “bridges” to complete the necessary connections within the framework of the square configuration. Here, the resistor bridges the connections between the transformer and both the first capacitor as well as the transistor. The second capacitor bridges the connection between the transformer and the inductor, and the third capacitor bridges the connection between the terminal block and the second transistor. The novel configuration achieves the necessary connections in the circuit board while allowing the arrangement of the components in a square footprint.

Other features and advantages of the invention will become apparent from the following detailed description, taken in conjunction with the accompanying drawings which illustrate, by way of example, the features of the invention

### BRIEF DESCRIPTION OF THE DRAWINGS

FIG. 1 is a top view of a first preferred embodiment of the circuit board of the present invention;

FIG. 2 is a bottom view of the circuit board of FIG. 1;

FIGS. 3-6 are four orthogonal side views of the circuit board of FIG. 1; and

FIG. 7 is a circuit diagram for the circuit board of FIG. 1.

### DETAILED DESCRIPTION OF THE INVENTION

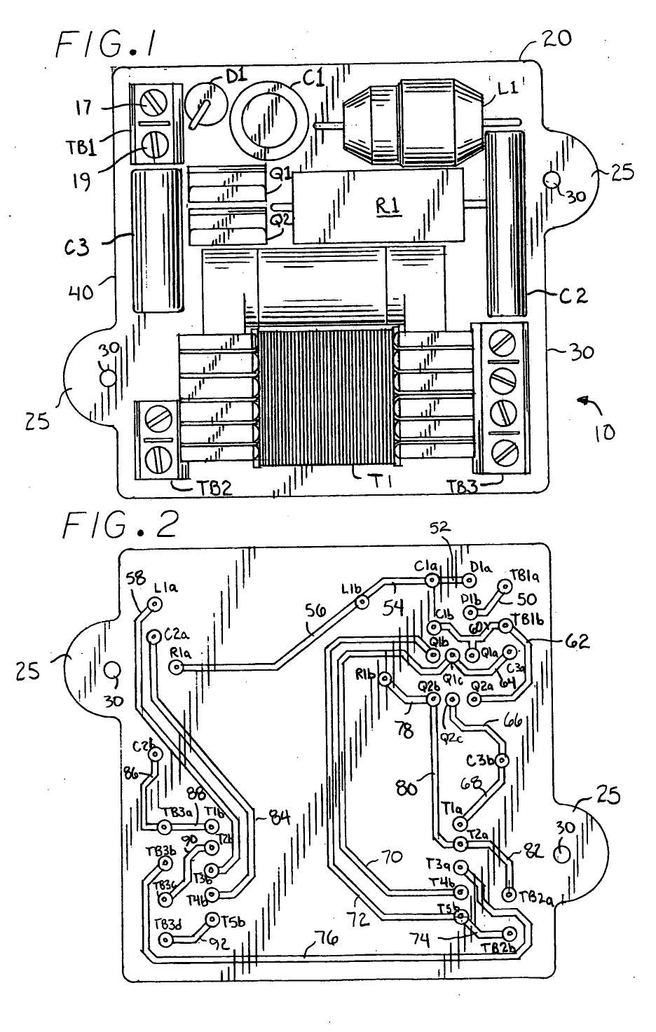

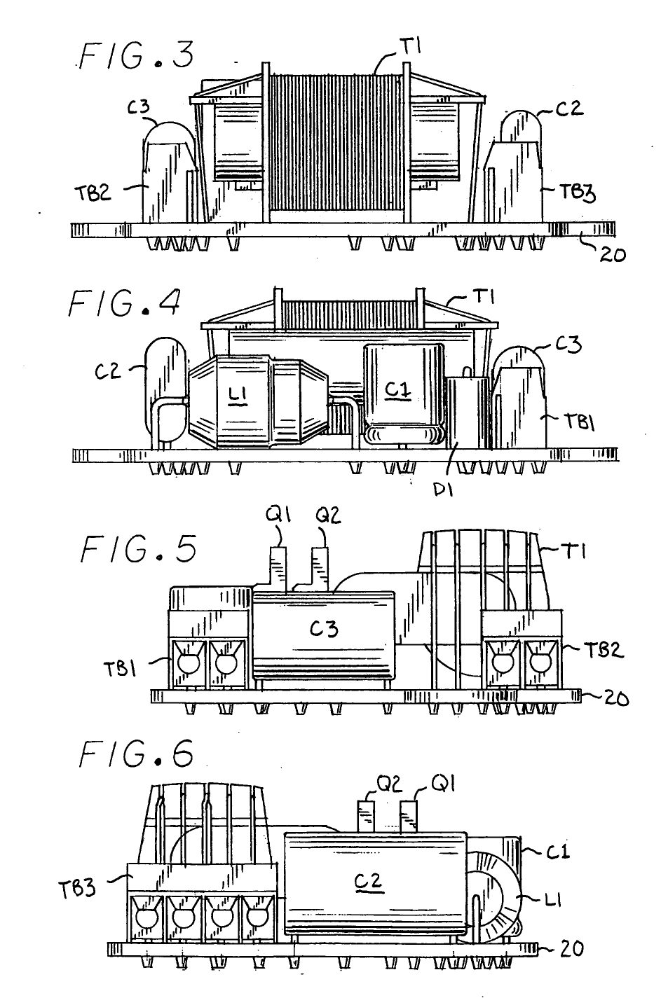

FIG. 1 illustrates the topography of a DC lighting fixture circuit board assembly having a square footprint. The breadboard 20 is a square 2¼″×2¼″ with mounting ears 25 on opposite sides including an aperture 30 for receiving a fastener (not shown) to mount the circuit board 10. The underside of the circuit board 10 illustrating the wiring schematic showing the conductive traces is shown in FIG. 2. FIGS. 3-6 illustrate the orthogonal views (back, front, right, and left) of the completed circuit board assembly.

The challenge in using a square circuit board is that components are bunched together and routing the wiring so as not to overlap other connections becomes problematic. The present invention overcomes this difficulty by strategically using several components themselves as bridges where current is routed not over traces on the breadboard 20 but rather across the elements serving as a bridge.

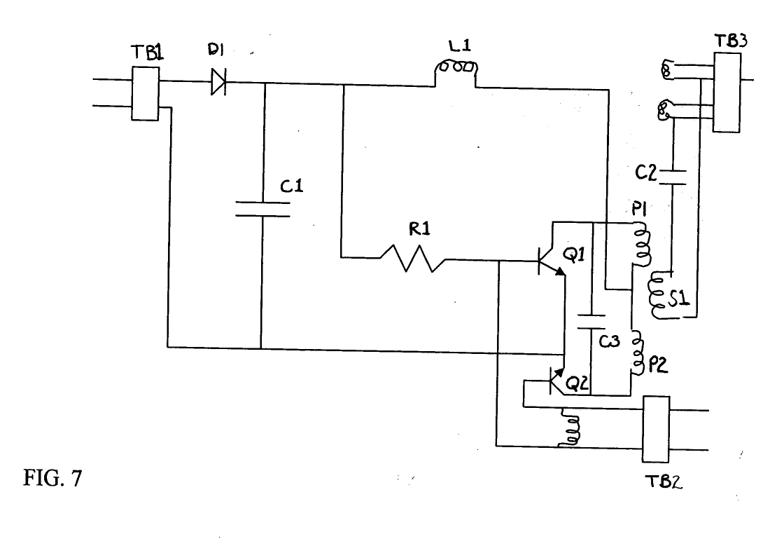

FIG. 7 illustrates the circuit to be arranged on the printed circuit board. A first terminal block TB1 provides the coupling for an input, and a second terminal block TB2 provides a coupling for an output. The output from TB1 is directed to a diode D1, and a first capacitor C1 provides a voltage across the two branches. The top branch includes two paths, the first leading to a resistor R1 and the second to an inductor L1. Two transistors Q1 and Q2 are coupled to the transformer primary windings P1 and P2, where capacitor C3 provides a voltage across the output of the two transistors. The secondary winding S1 of the transformer is connected to a second capacitor C2, and the capacitor C2 and the secondary winding S1 are both connected to a terminal block TB3 serving as the main output of the circuit board assembly 10.

To accomplish the foregoing circuit on a circuit board having only slightly more than five square inches of available surface area is a difficult challenge that is solved by the present invention. The arrangement of the present invention may be suited for two separate lights each having high and low voltage leads. Referring to FIGS. 1 and 2, terminal block TB1 is disposed in a first corner and includes two couplings 17, 19 for connecting a first pair of electrical leads. A diode D1 is connected to the terminal block TB1 at a first lead, and a capacitor C1 is connected to the diode D1. The capacitor C1 is also connected to the second lead of the terminal block TB1 to apply a voltage across the diode D1. An inductor L1 is placed adjacent the capacitor C1 such that the terminal block TB1, the diode D1, the capacitor C1, and the inductor L1 are all aligned along a first edge 20 of the circuit board. A resistor R1 is disposed between the inductor and a six winding transformer T1, and two transistors Q1, Q2 are disposed between the capacitor C1 and the transformer T1. Second and third capacitors C2, C3 are aligned on respective second and third edges 30, 40 of the circuit board and envelope the resistor R1 and the transistors Q1, Q2. Along the second edge of the circuit board 30 is a terminal block TB3 which is connected to the windings of the transformer T1. This arrangement results in a compact, space efficient circuit board and is shown in FIG. 1.

The traces or electrical connections for the arrangement of electrical components in FIG. 1 is shown in FIG. 2. Terminal block TB1 includes first and second terminals TB1a,b, respectively. The first terminal TB1a is connected by a trace 50 to the second terminal D1b of the diode D1. The first terminal D1a of the diode D1 is connected by trace 52 to the first terminal C1a of the capacitor C1. Capacitor C1 is then connected via trace 54 to the inductor L1 at terminal L1b. Trace 56 then connects the inductor L1 at terminal L1b to the first terminal R1a of the resistor R1.

The inductor L1 is also connected to the third winding T3b of the transformer T1 via trace 58. The terminal block TB1 at the second terminal TB1b is connected via trace 60 to the capacitor C1 at the second terminal C1b, as well as the first transistor Q1 at Q1a. The terminal block TB1 is also connected at the second terminal TB1b to the second transistor Q2 via trace 62 to the terminal Q2a. Capacitor C3 is connected at a first terminal C3a along trace 64 to the first transistor Q1 at terminal Q1c, and also connected at a second terminal C3b along trace 66 to the second transistor Q2 at terminal Q2c. The capacitor C3 is also connected at the second terminal C3b via trace 68 to the first winding T1a of the transformer T1. The first transistor Q1 at terminals Q1b and Q1c is connected to the transformer T1 via traces 70, 72 at T5a and T4a. The transformer T1 at T5a is connected to the terminal block TB2 at terminal TB2b along trace 74, and is connected at T3a to the terminal block TB3 along trace 76 to TB3b.

The transistor Q2 is connected to the resistor R1 along trace 78 between Q2b and R1b, and is connected to the transformer T1 along trace 80 between Q2b and T2a. The transformer T1 is also connected to the terminal block TB2 along trace 82 between T2a and TB2a. The capacitor C2 is connected to the transformer T1 between terminals C2a and T4b along trace 84, and is connected to the terminal block TB3 along trace 86 between terminals C2b and TB3a. The terminal block TB3 is connected to the transformer along three separate traces 88, 90, and 92. Trace 88 connects terminal TB3a to T1b, trace 90 connects terminal TB3c to T2b, and trace 92 connects terminal TB3d to T5b.

With the foregoing connections and couplings, it can be thusly seen that the capacitor C3 serves as a bridge spanning over traces 62 and 66. Moreover, resistor R1 serves as a bridge that spans over traces 70 and 72. Finally, capacitor C2 serves as a bridge that spans over traces 58 and 84. The strategic use of the electrical components to bridge over the traces enables the square configuration to exist. It is also possible to use the inductor L1 to span other traces if necessary, although the example of FIGS. 1 and 2 did not require the inductor to serve in this capacity.

The strategic use of the resistor R1, second capacitor C2, and third capacitor C3 to span other traces and serve as a bridge permits the compact arrangement of the electrical components of the present board into a square configuration. Other combinations may be contemplated, where such other combinations would be within the spirit of the invention exemplified by the foregoing example.

I claim:

1. A circuit board for a lighting fixture comprising:
a substantially square board, said board including circuitry components comprising:
first and second terminal blocks along a first side and a third terminal block along a second side
a diode adjacent said first terminal block and electrically connected thereto;
a first capacitor adjacent said diode and electrically connected thereto;
an inductor adjacent said first capacitor and electrically connected thereto;
a transformer disposed between said second and third terminal block and electrically connected to said inductor;
a second capacitor adjacent said third terminal block, said second capacitor electrically bridging the connection between said transformer and said inductor;
a first transistor adjacent said first capacitor and electrically connected to said transformer and said first terminal block;
a second transistor adjacent said first transistor and electrically connected to said transformer;
a third capacitor adjacent said first terminal block, said third capacitor bridging the connection between the first terminal block and said first transformer; and
a resistor connected to said second transistor and said inductor, said resistor bridging the connection between the first transistor and the transformer.

2. The circuit board of claim 1 further comprising offset ears extending outwardly from opposite sides of said board.

3. The circuit board of claim 1 wherein said transformer has six windings.

4. The circuit board of claim 1 wherein said inductor also serves as a bridge.

5. The circuit board of claim 1 wherein said circuitry components are arranged in a square configuration.

6. A square circuitry board for a DC lighting fixture comprising:
first, second, and third capacitors;
a resistor;
an inductor;
first and second transistors;
a diode; and
a transformer;
wherein said square board includes wiring for interconnecting components thereon, and said resistor and at least two capacitors serve as bridges to cross over at least one of said wirings to complete said circuitry.

7. The square circuitry board of claim 6 wherein said inductor further serves as a bridge to cross over at least one of said wirings to complete said circuitry.

8. The square circuitry board of claim 6 wherein each side of said square board does not exceed 2 and one quarter inches in length.

9. The square circuitry board of claim 6 wherein said resistor and said at least two capacitors each bridge at least two wirings each.
